(19) United States
(12) Patent Application Publication
(10) Pub. No.: US 2025/0138523 A1
(43) Pub. Date: May 1, 2025

(54) Computer-Implemented Method for Checking Load Circuits of a Technical Installation

(71) Applicant: Siemens Aktiengesellschaft, Muenchen (DE)

(72) Inventor: Markus PAL, Oberwart (AT)

(21) Appl. No.: 18/682,479

(22) PCT Filed: Aug. 3, 2022
(86) PCT No.: PCT/EP2022/071798

§ 371 Date: Feb. 9, 2024

(30) Foreign Application Priority Data
Aug. 11, 2021 (EP) 21190766

(51) Int. Cl. G05B 23/02; G01R 19/25

(52) U.S. Cl. CPC G05B 23/0256; G01R 19/2513

(57) ABSTRACT

A method for checking load circuits in a control system of an installation that includes load circuits, each having at a load unit, a control unit and a power supply that supplies load circuits with a supply voltage and/or current that are variable via output channels, wherein the control unit controls output channels and control outputs of the control unit via signals, where established installation states are predefined and each assigned with parameters to be determined, reference values and present parameter values are then determined for particular predefined installation states and compared with applicable reference values, a divergence list is filtered using installation states stored for elements, based on division of installation states into basic states and combination states and using the parameter values stored for the elements, and a result list is generated that can be forwarded and/or output for further processing.

### CROSS-REFERENCE TO RELATED APPLICATIONS

This is a U.S. national stage of application No. PCT/EP2022/071798 filed 3 Aug. 2022. Priority is claimed on European Application No. 21190766.6 filed 11 Aug. 2021, the content of which is incorporated herein by reference in its entirety.

### BACKGROUND OF THE INVENTION

### 1. Field of the Invention

The present invention relates generally to the field of electrical engineering, in particular to the field of power electronics and power electronic circuits and, more specifically, relates to a method for checking load circuits of a control system of a technical installation, where in addition to at least two load circuits, each having at least one load unit (for example sensor, actuator, relay, contactor, solenoid valve, and/or servomotor), the control system has at least one control unit and a clocked power supply that is used to supply the at least two load circuits with a variable-level supply voltage and/or supply current via at least two output channels, and where the at least two output channels and control outputs of the control unit are controlled by signals from the control unit, thereby producing different installation states.

### 2. Description of the Related Art

Complex installations and/or machines are used today in many fields, especially in industrial production and manufacturing, in automation technology, etc. An installation is to be understood as meaning a planned combination of components (for example, machines, devices and/or apparatuses) that are spatially related and interlinked in respect of function, control and/or safety. Such installations (for example, a production plant, or manufacturing facilities) and their components are noticeably becoming increasingly complex.

To ensure the efficient operation of technical installations and complex machines, control systems are therefore usually used to operate the machine or installation as autonomously and independently of human intervention as possible. Such a control system is therefore used to determine parameter values of the installation or machine via sensor or measuring units and to control actuator units or load units (for example, contactors, solenoid valves, visual or audible warning signals, motor units, and/or display units) accordingly depending on the parameter values determined. The control system of the installation/machine usually has a control unit for evaluating the parameter values supplied by the sensor and measuring units and for controlling the actuator units (for example, servomotor, warning signal, and/or display unit). Measurement signals from sensor and measuring units can be received by the control unit via corresponding inputs or the actuator units can be controlled by signals via corresponding control outputs. The control unit can also be used to connect or disconnect different load units, such as relays, contactors, and/or solenoid valves actuated by an electromagnet, using signals via the corresponding control outputs of the control unit, for example, in accordance with process-related requirements. A programmable logic controller or PLC, a microcontroller or an industrial PC, for example, can be used as the control unit.

In addition, such a control system has at least one clocked power supply (for example, a switched-mode power supply) by which an unstabilized input voltage is converted into a constant output voltage (for example, 24 volts) for supplying the load units of the control system. A power supply of this type, such as the SITOP PSU8600 from Siemens, has, for example, at least two or more outputs for directly connecting load circuits. These outputs are used as output channels and can be controlled by control signals from the control unit. Alternatively a clocked power supply can be used to which, for example, a module such as a switchable fuse unit, can be connected via an output of the power supply, said unit providing, for example, at least two separately switchable output channels. Load circuits with at least one load unit or comprising a group of load units can be connected to the individual output channels of the power supply or switchable fuse unit. The respective load circuit is then supplied with a supply voltage (for example, 24 volts) and/or a supply current by the power supply via the respective output channel.

To control the output channels of the power supply or switchable fuse unit, appropriate signals are provided for example by the control unit. These signals are used to switch the voltage and/or current supply of the respective load circuit on or off. The control unit can thus control the output channels and influence the supply voltage or the supply current in the output channels or for the respective connected load circuit.

In the case of a power supply having two or more output channels, for example, the voltage and current for each output channel can be set and monitored individually. This means that, for example, the respective supply voltage and/or the load current for the respective connected load circuit can be measured and monitored for each output channel of the power supply. This enables, for example, the current consumption or voltage present in a load circuit to be determined and changes in the current consumption or voltage due to control and switching actions of the control unit of the control system in said load circuit to be documented.

After setup or expansion, or during commissioning of a complex machine or installation, but also during operational use, checking for faults is an essential aspect in ensuring smooth and safe operation of the installation. Particularly during setup, expansion or commissioning, timely detection of component defects and wiring faults in the installation, particularly in the installation's control system, is important. Wiring faults are to be understood primarily as meaning faults when connecting one or more load units to a load circuit or to an output channel of the power supply. Timely detection of defective components in load circuits and wiring faults ensures smooth operation in the installation, for example, after expansion and/or during commissioning and, in particular, protects sensor and/or actuator units from damage or destruction. In addition, it is important to quickly detect and pinpoint faults (for example, cable breakage in a load circuit, malfunctions and/or defects in load units, for example, due to wear and tear) during the operational use of the system to avoid a long troubleshooting process and possibly a lengthy installation downtime.

WO 2021/037835 A1 describes a method for checking load circuits of a control system in a technical installation and for facilitating detection and pinpointing of component defects and wiring faults. In addition to at least two load circuits, each comprising at least one load unit (for example, contactor, solenoid valve, sensor unit, and/or actuator unit), the control system has at least one control unit and a clocked power supply. The power supply supplies the at least two load circuits with a supply voltage or a supply current via at least two output channels. The output channels and the control outputs of the control unit are controlled via signals from the control unit, thereby producing or adjusting different installation states. To check the load circuits, reference values for current or voltage or other signals for predefined installation states are first determined and stored. For a predefined installation state, at least one output channel is switched on, causing the respective associated load circuit to be supplied with a predetermined supply voltage or a predetermined supply current by the power supply. In addition, for an installation state, a control output of the control unit can be activated to control a load unit (for example, a switching unit, a relay, and/or a contactor) and, for example, switch it on or off in the load circuit. This means, for example, that least one output signal and/or control output of the control unit can be activated for an installation state. In a test phase, predefined installation states are run through (processed) and current values present are measured at predefined voltage values of the supply voltage or voltage values present are measured at predefined values of the supply current, at least at any output channel that is switched on. In order to detect any defective or faulty load circuits, the currently measured values are compared with the corresponding stored reference values. If the respective comparison result falls outside a predefined tolerance range for an installation state, then the at least one load circuit that was activated in that installation state is displayed.

However, if the method described in WO 2021/037835 A1 is used in its entirety in a complex installation, large amounts of raw data are generated for the user to check the installation.

Much raw data concerning installation states or information about associated load circuits is determined, which can only provide limited useful information on the present state of the installation, or that can be used to pinpoint a component defect and/or a wiring fault. The raw data or information provided by the method can, for example, be divided into three groups. The first group consists of information that provides useful information about the condition of the system and can ideally be used for troubleshooting. A second group consists, for example, of information that has no additional informative value regarding the condition of the system (i.e., defects and wiring faults) and is useless for this purpose. A third group is information or raw data that does provide useful information about the condition of the system, but whose information content is redundant. In order to access the first group of information or raw data, i.e., the information relevant for troubleshooting, after performing the method as disclosed in WO 2021/037835 A1, it is currently necessary to check,, e.g., manually, all the raw data provided by the method. Especially for complex installations, this can be extremely time-consuming as a way of finding component defects, and/or wiring faults, in the case of a large number of load circuits.

### SUMMARY OF THE INVENTION

In view of the foregoing, it is therefore an object of the invention to provide a method for checking load circuits of an installation or a control system of an installation, providing considerably simplified and accelerated detection and pinpointing of component defects and/or wiring faults as compared to the prior art.

These and other objects and advantages are achieved in accordance with the invention by a computer-implemented method for checking load circuits of a control system that comprises at least one control unit and one power supply in addition to at least two load circuits each having at least one load unit (for example, contactor, solenoid valve, sensor unit, and/or actuator unit). The power supply supplies the at least two load circuits with a supply voltage and/or a supply current via at least two output channels. The at least two output channels and the control outputs of the control unit are controlled by the control unit via corresponding signals, thereby producing different installation states. The method comprises:
predefining installation states, where the installation states are sub-divided at least into basic states, in which at least one output channel or control output is switched active, and combination states resulting from a combination of at least two basic states, and where parameters to be determined are assigned to each installation state;
determining and storing reference values of the parameters for the respective predefined installation states;
determining and storing present parameter values for the respective predefined installation states;
comparing the present parameter values determined with the corresponding reference values, where the present parameter values determined that deviate from the corresponding reference values are stored with the respectively assigned installation state as elements in a divergence list; and
filtering the divergence list to generate a results list, where a check of each element in the divergence list is performed to determine whether the installation state of the respective element is a basic state or a combination state. If the installation state of the respective element is a basic state, then the respective element is transferred to the results list. If the installation state of the respective element is a combination state, then a check is performed to ascertain whether the divergence list contains at least one element having, as an installation state, one of the basic states from which the combination state of the element is composed. If no such element is found in the divergence list, then the respective element is transferred to the results list. If at least one element having one of the basic states of which the combination state of the respective element is composed is found in the divergence list, then the determined parameter values of the elements are checked and the respective element is only transferred to the results list if its parameter value differs in respect of value (i.e., the determined parameter value) or type (i.e., the type or kind of parameter to be determined, such as voltage, current, temperature, sensor value, and/or signal value) from the parameter value of the at least one element found.

The main aspect of the method in accordance with the invention is that a corresponding two-fold filtering of the present parameter values determined for the respective predefined installation states considerably simplifies and speeds up the detection and pinpointing of component defects and/or wiring faults in an installation or complex machine. Initial filtering is achieved by comparing the currently determined parameter values with the corresponding reference values for the respective specified installation states. Further filtering of the information is achieved by filtering the comparison result, i.e., the divergence list, where redundant information is removed based on the installation states sub-divided at least into basic states and combination states. Ideally, both installation states and parameter values with redundant information are filtered out and only more useful information in the form of elements consisting of an installation state and a determined parameter value of a parameter assigned to the installation state is included in the results list. After a run-through of the method, a user will be provided with a results list containing only more useful information or data for further processing and analysis of the installation.

The filtering operations carried out as part of the method, i.e., comparison of parameter values currently present with corresponding reference values and filtering of the divergence list, filters out unusable and/or redundant information and thus significantly reduces the amount of data to be further processed or analyzed. With the aid of this reduced data volume (i.e., using the results list containing relevant elements having a parameter value at variance with the corresponding reference value and respective associated installation state), troubleshooting can then be narrowed down and a significant time saving for further processing can therefore be achieved. The corresponding installation states and any deviating parameter values indicate the load circuits of the control system that are to be analyzed, in which, for example, wiring faults, component defects and/or other defects (for example, cable breakage) may be present. Faulty wiring of a load circuit and/or an incorrectly inserted or installed load unit, for example, can thus be detected very easily, quickly and possibly automatically, if, for example, predefined installation states are run through (processed) in the form of a test program.

Another advantage of the method in accordance with the invention is that it is performed in a computer-implemented, i.e., automated, manner such as in the control unit or in another processing unit (for example, computer unit, or industrial PC) that can be connected to the installation. In particular, the filtering of the divergence list and the generation of the results list can be carried out automatically, for example, on a computer unit separate from the installation, which saves a considerable amount of time and reduces the analysis involved.

It is advantageous if the elements of the results list that have a basic state as the installation state are checked to ascertain whether parameter values of matching value and type determined for these elements are listed. In other words, the results list is checked to ascertain whether, for all the elements in the results list having a basic state as the installation state, a particular parameter value appears which has the same value and the same parameter type (for example, voltage at an output channel, current at an output channel, and/or signal value at a control output or input).

This parameter value is then filtered out of the results list or, if no other parameter value differs, then the corresponding element (i.e., the respective parameter and the associated installation state or basic state) is filtered out of the results list. A reference to this parameter value or the respective element of the results list is then inserted at the end of the list, for example. This additional filtering of the results list relates to the control unit's output channels or control outputs that must remain permanently activated while the method is being carried out, for example, as the control unit is continuously supplied with voltage or current via this output channel or, for example, air pressure is always present as a sensor value. Such permanently activated output channels or control outputs or inputs of the control unit can, for example, generate parameter values for all the installation states. If one of these parameter values deviates, then that parameter value is indicated as deviating for all the installation states, for example, and is listed as deviating in the results list and especially for those installation states that are defined as basic states. The additional filtering removes these parameter values and any associated installation states (i.e., the corresponding elements) from the results list and keeps the results list consistent and short for further processing.

It is also advantageous if the results list is forwarded and/or output for further processing, where elements of the results list are consolidated with identical installation states. The results list can be output in the form of a text file, for example, which can then be evaluated in a data processing unit (for example, computer unit, industrial PC) or manually by a user. Alternatively, the results list can be evaluated and processed for example such that the user is shown the load circuits in which deviating parameter values were determined, for example, via a display of the data processing unit or via an output unit connected to the data processing unit. Ideally, elements having identical installation states are consolidated in the results list in order to keep the results list short and consistent and provide the user with a simple overview.

In an advantageous embodiment of the invention, at least one voltage at least one of the at least two output channels, a current at least one of the at least two output channels, a signal at least one control output of the control unit and/or a signal at least one input of the control unit are predefined as parameters to be determined depending on the respective installation state. For example, only voltage and/or current at output channels that are switched on in the respective installation state can be specified as parameters to be determined. In addition, however, voltage and/or current at output channels that are switched off in the respective installation state can also be determined as parameters. Determining signals at the control outputs and inputs of the control unit as parameters also facilitates detection of defects and/or wiring faults in the installation. In the case of the control outputs, for example, values of control signals for switching load units on or off in load circuits can be interrogated. For example, values from temperature sensors, speed sensors, proximity switch idle signals, and/or function signals, can be interrogated as parameters at the inputs of the control unit.

In addition, it is advantageous if the predefined installation states are run through (processed) in the same sequence when determining the reference values of the predefined parameters and when determining the present values of the predefined parameters. To determine the reference values of the predefined parameters, the sequence of the predefined installation states can be selected as desired. However, this sequence should be adhered to when determining the present values of the specified parameters, for example, in the self-test phase, test commissioning of the installation after it has been installed, and/or extended. This provides a simple way to avoid deviations between the currently determined parameter value and the corresponding reference value, which can occur, for example, due to heating of the system, and/or capacitive charging of loads in load circuits in the installation, when the predefined installation states are run through.

It is also advantageous if, for the predefined installation states, a plurality of supply voltage values are predefined with which at least one of the at least two load circuits, in particular a load circuit activated in the respective installation state, is supplied in the respective predefined installation state. The reference values as well as currently to be determined parameter values for the respective installation state are measured for the predefined supply voltage values. Each different value of the supply voltage for the at least one activated load circuit in the respective installation state constitutes a separate, new installation state for which reference values and parameter values for the assigned parameters are to be determined. The predefined voltage values for the supply voltage for the respective installation state can also be predefined for the power supply by the control unit or set on the externally connected output branch.

In addition, it is recommended that the predefined voltage values be increased in predefined voltage steps from an initial supply voltage (for example, 0 volts) up to a nominal voltage (for example, 28 volts) or up to an operating limit of the at least one load unit connected to the respective load circuit. By increasing the supply voltage in predefined voltage steps (for example, in steps of 2 volts), for example, load-circuit-specific and/or parameter values typical for the respective load unit (for example, current values) can be measured that provide additional support for detecting wiring faults and any malfunctions.

For example, small sensors can have a linear regulator with internal electronics by which the sensor is only switched on from a particular supply voltage (for example, 5 volts or 12 volts) upwards and which, for example, keeps the power consumption constant up to a particular voltage (for example, 28 volts). More powerful loads, such as control units, have, for example, a step-down converter, to generate an internal auxiliary voltage and reduce the current as the supply voltage increases, for example. A contactor as a load unit has, for example, a linearly increasing current consumption as the supply voltage increases. A DC motor, for example, can have a very low resistance at low voltage and for example absorb a high current, which increases or may even decrease in a flat curve, for example, as the rotary movement begins.

As an alternative to a gradual increase in the supply voltage at least one switched-on output channel of the power supply, it can also be advantageous if the predefined voltage values for the supply voltage are increased in the form of a linear voltage ramp with a predefinable gradient from an initial supply voltage (for example, 0 volts) up to a predefined nominal voltage (for example, 28 volts) or an operating limit of the at least one load circuit unit connected to the respective load circuit.

Alternatively, instead of voltage values for the supply voltage, a plurality of current values can also be predefined for the supply current with which the at least one activated load circuit is supplied in the respective predefined installation state. These current values can also be increased in steps, for example, from an initial current up to a predefined maximum current value, or linearly with a predetermined gradient.

In addition, it is advantageous if a predefinable wait time is observed when determining the reference values and when determining the present parameter values in the event of a change from one predefined installation state to another predefined installation state. This makes it possible, for example, to eliminate as far as possible the effects of current and/or voltage fluctuations occurring when the supply voltage is connected to the respective load circuit (i.e., when the corresponding output channel is switched on), or when the voltage value of the supply voltage changes due to the respective load units in the load circuit, on the measurement of the respective reference values or the present parameter values, in particular on current or voltage values. In addition, by observing the specified wait time, it can be ensured that, for example, parameters of a previous installation state have already decayed. For example, after deactivation of the installation state in which the associated load circuit was activated, a sensor unit may deliver randomly in the subsequent installation state, for example, as the supply voltage in the associated load circuit or output channel only decays slowly.

The predefinable wait time for determining the parameter values of an installation state can be selected, for example, such that a stable current has been attained in at least one active load circuit of the installation state, said current having, for example, a relatively low fluctuation (for example, 3% deviation in one second), or such that a current or voltage has decayed in at least one load circuit which was activated in the respective previous installation state. A predefined value for the wait time for the respective load circuits or the corresponding load units can, for example, be determined during determination of the reference values and then used for determining the parameter values. This allows wait times for load units or load circuits without a significant settling time, for example, to be reduced to a minimum. For load units with relatively long settling times, for example, a safety reserve can be provided in addition to the predefinable wait time in order to obtain stable values for the parameters to be determined.

Ideally, the reference values of the parameters to be determined for the respective installation states are determined, for example, during a planning and development phase of the installation by means of a reference installation, for example, at the manufacturer. The corresponding reference values are therefore available for example when commissioning systems of the same type (for example, series installation/machine) at the respective installation site, and can be used to check whether the load circuits have been wired correctly and whether the correct load units have been installed at the planned locations or in the planned load circuits and do not have any component defects.

Alternatively, the reference values of the parameters to be determined for the respective installation states can be determined during a commissioning phase of the installation to be checked (for example, during test commissioning at the manufacturer) or derived from parameter values that are measured continuously for different installation states at the respective output channels and/or control outputs of the control unit, for example, during ongoing operation of the system. In other words, the reference values are ideally derived from previous measured values that were acquired for different installation states (for example, during ongoing operation, during commissioning at the manufacturer or at the user). This is particularly useful if, for example, an installation is partially dismantled, transported and reinstalled. When the system is recommissioned or switched back on, it is then very easy to check that the load circuits of the system control system are correctly wired and that the load circuits and load units are functioning correctly.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The invention will be explained in the following using examples and with reference to the accompanying drawings, in which:

FIG. 1 shows a schematic and exemplary structure of a control system of an installation for performing the method for checking load circuits in accordance with the invention; and FIG. 2 shows an exemplary sequence of the method for checking load circuits of a control system in an installation.

### DETAILED DESCRIPTION OF THE EXEMPLARY EMBODIMENTS

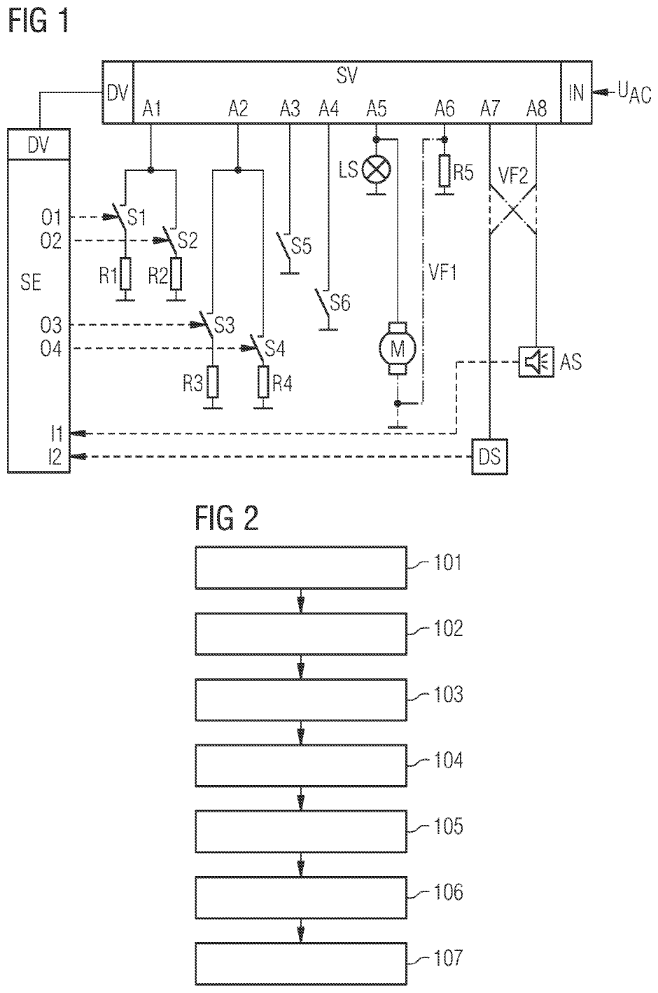

FIG. 1 schematically illustrates an exemplary control system of a technical installation. The exemplary control system comprises at least one control unit SE that can be formed, for example, as a programmable logic controller (PLC), a microcontroller or an industrial PC. The control unit SE has, for example, control outputs O1, . . . , O4 for controlling load units, for example, for switching switching units S1, . . . , S4. Alternatively, the switching units S1, . . . , S4 can also be part of an output module of the control unit SE, in particular a digital output module with a programmable logic controller or PLC. The control outputs O1, . . . , O4 of the control unit SE are formed, for example, as digital outputs. In addition to or instead of the digital control outputs O1, . . . , O4, the control unit can also have analog outputs to which, for example, actuator units or switching units can be connected. The control outputs O1, . . . , O4 are used to control the installation or machine during operation via control signals and thus put it into different operating or installation states. In addition, the control unit SE has digital inputs 11, 12, for example, via which signals from load units, such as sensor units DS, AS, are received. With the signals received at the inputs 11, 12, the control unit SE obtains information about what is currently happening in the installation, thereby enabling appropriate control and regulation processes to be triggered. The control unit SE can also have analog inputs for connecting and interrogating sensor units.

The exemplary control system also has a clocked power supply SV that is connected to a voltage supply UAc (for example, a 3-phase AC voltage) via an input side IN. In addition, the power supply has, for example, eight output channels A1, . . . , A8 to which the load circuits of the control system are connected directly, for example. The load circuits of the control system are supplied with a supply voltage (for example, 24 V DC) or a supply current from the power supply SV via the output channels A1, . . . , A8. As in the case of the SITOP PSU8600, for example, a value of the supply voltage delivered to the respective load circuit can be set and monitored individually for each output channel A1, . . . , A8. In the typical control system shown in FIG. 1, for example, the supply voltage delivered to the respective load circuit is predefined for the associated output channel A1, . . . , A8.

Alternatively, the power supply SV can be designed such that for example an external module (for example, an externally switchable fuse unit) having at least two output branches is connected. The at least two output channels A1, . . . , A8 for connecting the load circuits are then provided by the external module. The output channels A1,., A8 can be switched separately, for example, and the respective load circuits are supplied with voltage or current via these output channels, where the voltage or current delivered to the respective load circuit can be individually adjusted and monitored.

In addition, the power supply SV and the control unit SE can have interface modules DV that can be used to establish, for example, a bidirectional data link for transmitting control signals and data information. For example, Profinet (Process Field Network), an open industrial Ethernet standard of the PROFIBUS user organization, can be used for the data link.

A separate power supply (not shown in FIG. 1) can be provided to supply voltage to the SE control unit. However, the control unit SE can also be supplied with the appropriate voltage directly from the power supply SV of the control system. For this purpose, the control unit SE can be connected, for example, to a first output channel A1 of the power supply SV. The first output channel A1 must then always be activated during the checking procedure to supply the control unit SE with voltage or current.

The load circuits, each having at least one load unit (for example, switching unit, actuator unit, and/or sensor unit), are connected to the output channels A1, . . . , A8. In the control system shown by way of example in FIG. 1, switching units S1, S2, S3, S4 and associated load resistors R1, R2, R3, R4 (for example, contactors) are connected to the first output channel A1 and to a second output channel A2, for example. The respective switching units S1, S2, S3, S4 can be switched on or off via corresponding signals at the respective control outputs O1, O2, O3, O4. Further actuator or switching units S5, S6 (for example, contactors, and/or solenoid valves), for example, are connected to a third and fourth output channel A3, A4 as load units. These switching units S5, S6 can be controlled by the control unit SE to switch an electric valve, a motor or a module for drive control, etc. on or off.

A light signal LS and a motor M, for example, for operating a fan unit, are connected to a fifth output channel A5, for example. A further load resistor R5, for example, is connected to a sixth output channel A6. Incorrectly, for example, the motor M or the fan unit is not connected from the fifth output channel A5 to ground (as shown by the dashed line) but is connected to the sixth output channel A6 due to a first wiring fault VF1 (for example, when setting up the installation or machine). The first wiring fault VF1 is shown as a dash-dotted line.

Load circuits, for example, comprising for example sensor units DS, AS such as a pressure sensor DS, and/or an audible signal unit AS, as load units are connected to a seventh and an eighth output channel A7, A8. Signals are supplied from the sensor units DS, AS to the digital inputs 11, 12 of the control unit SE. A second example of a wiring fault VF2 is shown for these load circuits, as a result of which the connection of the sensor units DS, AS to the respective output channels A7, A8 is reversed (again shown via a dash-dotted line). The correct wiring is shown by a dashed line in FIG. 1. Due to the second wiring fault VF2, the audible signal unit AS is supplied with voltage via the seventh output channel A7 and the pressure sensor DS via the eighth output channel A8. However, the respective signal outputs of the pressure sensor DS and the audible signal unit AS are connected to the respective correct digital inputs 11, 12 of the control unit SE, which means that, for example, the pressure sensor DS reports an input signal to the digital input 12 of the control unit SE when a threshold value is reached, and the audible signal unit AS emits a function signal to the digital input I1 of the control unit SE during operation.

FIG. 2 shows an example of a sequence of the method in accordance with the invention for checking load circuits of a control system of an installation, an example of which is shown in FIG. 1.

In a definition step 101, installation states are predefined for checking the load circuit of the installation control system. An installation state represents an operating state of the installation or of the control system that is defined or produced via a switch setting by the control unit SE and activated load circuits, i.e., load circuits supplied with supply voltage. This means that for an installation state, depending on the signals provided by control unit SE, for example, one or more output channels A1, . . . , A8 and thus the respective connected load circuits are activated and/or the respective load units in the load circuits are switched on or off via control outputs O1, . . . , O4. In a predefined installation state, at least one output channel A1, . . . , A8 and/or control output O1, . . . , O4 is therefore switched on. The respective installation states and thus the respectively switched-on and switched-off output channels A1, . . . , A8 as well as the respectively switched-on and switched-off control outputs O1, . . . , O4 are predefined by the control unit SE. As a result, the control unit SE can selectively activate and deactivate at least a majority of the load units and thus very easily produce the predefined installation states. The output channels A1, . . . , A8 of the power supply SV can be activated for example via the data link DV between the control unit SE and the power supply SV.

In addition, the installation states predefined for the method are divided at least into basic states and combination states in the definition step 101. A basic state represents an installation state in which at least one output channel A1, . . . , A8 or control output O1, . . . , O4 of the control unit is switched active or switched on. For the control system shown by way of example in FIG. 1, for example, installation states in which the first, second, third, etc. output channel A1, . . . , A8 alone and thus the respective associated load circuit is activated can be specified as basic states. The remaining output channels A1, . . . , A8 remain switched off. In addition, switching-on of one of the control outputs O1, . . . , O4 and therefore, for example, switching-on of the respective controlled switching unit S1, S2, S3, S4 or switching-on of the respective load unit R1, R2, R3, R4 can represent a basic state. In addition, simultaneous activation of a plurality of output channels A1,., A8 and/or a plurality of control outputs O1, . . . , O4, for example, can also be defined as a basic state. In the installation control system shown in FIG. 1, for example, simultaneous activation of a first control output O1 and a second control output O2 of the control unit SE in addition to the activated first output channel A1 can be defined as a basic state. The associated switching elements S1, S2 in the load circuit connected to the first output channel A1 of the power supply SV are then switched, for example, and the associated load resistors R1, R2 are connected simultaneously. Similarly, for example, the installation states for the second output channel A2 of the power supply SV can also be combined and defined as a basic state.

A combination state is then to be understood as meaning a combination of at least two installation states that are specified as basic states. This means that in the control system shown in FIG. 1, for example, the switching-on of the first output channel A1 can be predefined as the first basic state and the switching-on of the first control output O1 can be predefined as the second basic state. A combination state would be when the first output channel A1 is first activated as the first installation state or first basic state and then, in addition to the first installation state or first basic state, the first control output O1, the sole activation of which constitutes the second basic state, is activated for a subsequent installation state, i.e., combination state.

In actual systems, basically more installation states, which are then set as basic or combination states as required, can be defined and used for the method. However, the definition step 101 should exclude installation states that are inappropriate, dangerous or not useful (for example, an installation state that unintentionally activates a pump, a drive or a valve). In addition, the installation states that are predefined or considered useful can be consolidated in the form of a test program which can be adapted, for example, for a self-test phase of an installation that is being put into operation, i.e., the installation states can be selected and predefined on an installation-and/or user-specific basis.

In addition, in definition step 101, a set of corresponding parameters to be determined is predefined for each predefined installation state. Depending on the predefined installation state, parameters such as voltage and/or current at one or more output channels A1, . . . , A8 and/or signal values at least one control output O1, . . . , O4 of the control unit SE can be interrogated. In addition, the inputs 11, 12 of the control unit SE can also be interrogated for predefined installation states, for example, for upcoming signal values from sensor units DS, AS. Such inputs (for example, temperature values, rpm values, steam pressure values, and/or function signals) can, for example, also be used to check the load circuit, particularly in the correct wiring of a sensor unit DS, AS.

In addition, a plurality of voltage values can be predefined for each of the predefined installation states, in particular for those installation states in which at least one output channel A1, . . . , A8 of the power supply is activated. For example, the different voltage values can be predefined on the respective output channel A1, . . . , A8 for the respective installation state by the control unit SE or, if necessary, set on the externally connected output branch. Each predefined voltage value of the supply voltage constitutes, with the associated installation state, a separate, new installation state, where a change in the supply voltage does not change the sub-division into basic and combination states. Alternatively, instead of voltage values, a plurality of current values can be predefined, where each predefined current value forms a separate installation state with the associated installation state.

To check the load circuits in accordance with the method, reference values of the parameters of the individual installation states predefined in the definition step 101 are determined in a reference step 102. This means, for example, that a predefined installation state (for example, a first installation state with the first output channel A1 of the power supply SV switched on, a second installation state with the first digital output O1 of the control unit SE activated) is produced via the control unit SE. Any sequence of installation states can be selected in reference step 102, ideally according to efficiency criteria. The reference values for the parameters predefined for the installation state are then determined, for example, the voltage and/or the current are measured at the switched-on output channel A1 and, if necessary, at the switched-off output channels A2, . . . , A8, signal values from control outputs O1, . . . , O4 and/or inputs I1, I2 of the control unit are interrogated. The determined reference values are then stored together with the respective installation state.

If a plurality of voltage values for the supply voltage of the at least one activated output channel A1, . . . , A8 (or current values) were predefined for an installation state in the definition step 101, in the reference step 102, for example, then the respective voltage value (or current value) for the at least one output channel A1, . . . , A8 is predefined or set externally by the control unit SE and the respective installation state is produced. The reference values of the parameters of the respective installation state and the respective voltage value (or current value) are then determined. For each predefined voltage value (or current value), the installation state is stored with the associated, determined reference values and with the predefined, set voltage value (or current value) as a separate installation state.

When changing from one predefined installation state to another predefined installation state, a predefined wait time can be provided, for example, for determining the reference values. In particular, if the predefined value of the supply voltage at the at least one switched-on output channel A1, . . . , A8 is changed (for example, a plurality of predefined voltage values for an installation state are run through), it can be useful to observe a predefined wait time between changing the voltage value of the supply voltage and determining the reference values, in particular when measuring current values in the at least one switched-on output channel A1, . . . , A8 of the power supply SV. In this way, for example, current fluctuations due to transients caused by the change in voltage, etc. are not measured, but parameter values present, in particular current values, are measured that are as static or constant as possible.

The reference values and any necessary or useful wait times can be determined in the reference step 102, for example, via a reference installation, for example, by a manufacturer in a development test phase (i.e., after development for example of a series installation). Alternatively or additionally, for example, in the case of user-specific installations or machines, the reference values and any wait times can be determined during initial commissioning of the system or machine or derived from measured values that are acquired for the predefined installation states during ongoing operation. The installation states can be stored with the reference values determined for the associated parameters, for example, in the control unit SE of the system, transferred to a control unit SE of a system of the same type and/or to a centrally available data processing unit (for example computer unit, or industrial PC) and stored there.

A self-test phase can be performed at installation prior to commissioning, for example, after transportation and reinstallation, extension or new installation of the respective installation or even during a restart during ongoing operation of the installation. In a measurement step 103, the predefined installation states are selectively produced by the control unit SE, for example, by commands via the data link DV to the power supply SV and, if necessary, via signals at the control outputs O1, . . . , O4 of the load units S1, . . . , S4 connected to the control unit SE. It is important that the predefined installation states are run through in the same sequence as the installation states when determining the reference values in reference step 102.

The predefined installation states can, for example, be selected in the definition step 101 from possible or useful installation states for the system and sub-divided into basic states and combination states. Before or during the reference step 102, for example, a list of the predefined basic and combination states can be created and stored, for example, in the control unit SE or in the data processing unit. This list can be processed, for example, in measurement step 103 in order to maintain the same sequence of installation states as in the reference step 102.

In addition, in measurement step 103, a plurality of supply voltage values (or current values) are also set for an installation state at least one switched-on output channel A1, . . . , A8 of the power supply (for example, by the power supply SV via a command from the control unit SE), provided that a plurality of voltage values (or current values) were predefined for this installation state in definition step 101. In order to run through the predefined voltage values of the supply voltage for the currently predefined installation state in measurement step 103, the supply voltage can, for example, be increased from an initial supply voltage (for example, 0 volts) up to a predefined nominal voltage (for example, 24 or 28 volts) in predefined voltage steps (for example, 2 volts). The predefined voltage values (or current values) of an installation state in predefined voltage steps (or current steps) can be run through analogously to reference step 102 for determining the reference values.

For each predefined installation state and any voltage value (or current value) predefined for the installation state, the present values of the parameters associated with the installation state are then measured or interrogated. This means, for example, that a present current value and/or voltage value is measured at the at least one output channel A1, . . . , A8 and/or at the other output channels and/or signal values are interrogated at the control outputs and/or inputs of the control unit SE for the respective installation state at a predefined voltage level. In addition, it should be noted that, in measurement step 103, the predefined wait time is also observed in the event of a change from one installation state to another installation state, if a predefined wait time was provided when the reference values were determined in reference step 102. The parameter values determined in the currently running measurement step 103 are then stored together with the respective installation state, including the predefined voltage values, if a plurality of voltage values were predefined for the respective installation state in the definition step 101, and can then be evaluated in relation to the corresponding reference values in a comparison step 104. The currently determined parameter values can, for example, also be stored together with the associated installation states in the control unit SE which then also performs an evaluation, for example. However, the currently determined parameter values and the associated installation states can also be transferred to a data processing unit for further evaluation and stored there.

In comparison step 104, which also represents a first filtering of the determined parameter values, the currently determined parameter values of each predefined installation state are compared with the corresponding reference values determined in reference step 102. The comparison can be performed in any order. When comparing a respective currently determined parameter value of a predefined installation state with the corresponding reference value of the same installation state, a check is performed to ascertain whether the respective currently determined parameter value deviates from the corresponding reference value. If a deviation is detected during the comparison, in a storage step 105 the respective parameter value is stored, together with the installation state and any predefined voltage value at which the parameter value was determined, as an element in a divergence list. Subsequently, for example, either the next currently determined parameter value of the respective installation state or a first currently determined parameter value of a next installation state is compared. If there is no deviation between a respective parameter value and the corresponding reference value of a respective installation state, then either the next currently determined parameter value of the respective installation state or a first currently determined parameter value of a next installation state is checked until all currently determined parameter values have been compared with the corresponding reference values.

For example, a tolerance range can be predefined for comparing the currently measured parameter values with the corresponding reference values. A check is then performed to ascertain whether or not the predefined tolerance range is exceeded when the respective, currently determined parameter value is compared with the corresponding reference value. In storage step 105, those currently determined parameter values are then stored together with the associated installation state as an element in the divergence list only if the tolerance range is exceeded when comparing with the corresponding reference value.

The predefined tolerance range can be specified, for example, in the form of a percentage or in the form of an absolute range. A tolerance range can be provided for all the load circuits of the installation or machine that are to be tested. However, it is also possible to predefine individual tolerance ranges for specific load circuits or to provide tolerance ranges, for example, for identical or similar load circuits.

The tolerance range can also be adjusted if, for example, after repeated use it is recognized that the predefined tolerance range has been selected, for example, too narrow or too wide.

After all the currently determined parameter values have been checked in comparison step 104 and the deviating parameter values together with the respective associated installation states have been stored in the divergence list in storage step 105, redundant information (i.e., elements from the currently determined parameter value and associated installation state) is filtered out of the divergence list in a filter step 106 based on the subdivision of the installation states into basic states and combination states.

For this purpose, a check is performed for each element of the divergence list to ascertain whether the installation state of the respective element is a basic state or a combination state. The elements in the divergence list can also be checked in any order. If the installation state of the respective element is a basic state, the respective element (i.e., parameter value and installation state) is transferred to a results list. In addition, if the installation state of the respective element is a combination state, then the system checks whether the divergence list contains at least one element having as the installation state one of the basic states from which the combination state is composed. If no such element is found in the divergence list, then the respective element (i.e., parameter value and installation state) is transferred to the results list. If, in the divergence list, at least one element is found that has one of the basic states that make up the combination state of the element currently being checked, then the determined parameter values of the elements are compared. The respective element currently being checked (i.e., parameter value and installation state) is only transferred to the results list if its parameter value differs in respect of value (i.e., the determined parameter value) or type (i.e., the type of the parameter to be determined, such as voltage, current, temperature, sensor value, and/or signal value) from the parameter value of the at least one element found. This means that if the parameter values of the respective element that has just been checked and of the at least one element found having one of the basic states from which the combination state of the respective element currently being checked is composed are of the same parameter value and parameter type, then the information of the respective element currently being checked is deemed to be redundant and this element is not transferred to the results list, i.e., is filtered out.

In addition, in filter step 106, those elements of the results list that have a basic state as the installation state can be checked to ascertain whether the elements contain currently determined parameter values that match with respect to value and type. In other words, the results list is checked to ascertain whether, for all the elements in the results list having a basic state as the installation state, a particular parameter value occurs that has the same value and the same parameter type (for example, voltage at an output channel, current at an output channel, and/or signal value at a control output or input,). This parameter value is then filtered out of the results list in filter step 106. If no other parameter value deviating from this basic state is found in the results list, then the corresponding element (i.e., the respective parameter and the respective associated installation state) is filtered out of the results list. A reference to this parameter value or the respective element can be inserted at the end of the results list, for example.

In an output step 107, the results list can then be forwarded and/or output for further processing. Elements of the results list with identical installation states can be aggregated. This means that in output step 107, for example, the results list is output as a text file in which, for example, the respective installation states with the respective deviating parameters are listed with determined parameter value and parameter type. The text file can then be evaluated for example in a data processing unit (for example, computer unit, or industrial PC) or manually by a user. Alternatively, the results list can, for example, be evaluated and processed, for example, such that the user is shown, for example, via a display, those load circuits of the installation control system in which deviating parameter values were determined. In the installation shown by way of example in FIG. 1, for example, the load circuits connected to the fifth and sixth output channels A5, A6 and having the first wiring fault VF1 and those connected to the seventh and eighth output channels A7, A8 and having the second wiring fault VF2 would then be displayed. The installation states with corresponding parameter values that were detected as deviating in the course of the method and whose information content is unique for finding the wiring faults VF1, VF2 would be found as an element in the results list.

The method described with reference to the figures can also be used for test procedures for installations with a reduced set of predefined installation states. This means that in order to check the load circuits, for example, as a test during ongoing operation to find, for example, defective components and/or cable breaks, more quickly, a certain number of installation states that are appropriate for the respective installation can be predefined and the method can be run through.

In addition, it is possible to use the method to determine an appropriately reduced set of installation states for reduced and time-efficient checking of the installation. For this purpose, in reference step 101 for measuring the reference values a “blank measurement” of the parameters of the respective installation states is performed prior to each of the respective installation states. This means that blank values of the parameters of the respective installation state are measured on the installation at rest before the respective installation state is brought about by the control unit SE. In comparison step 104, the measured blank values are then compared with the determined reference values for each installation state and filter step 106 is applied to the determined divergence list. As a result, installation states relevant for checking the installation can be recognized and thus a reduced set of installation states can be determined for the method.

Thus, while there have been shown, described and pointed out fundamental novel features of the invention as applied to a preferred embodiment thereof, it will be understood that various omissions and substitutions and changes in the form and details of the methods described and the devices illustrated, and in their operation, may be made by those skilled in the art without departing from the spirit of the invention. For example, it is expressly intended that all combinations of those elements and/or method steps which perform substantially the same function in substantially the same way to achieve the same results are within the scope of the invention. Moreover, it should be recognized that structures and/or elements and/or method steps shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1-10. (canceled)

11. A computer-implemented method for checking load circuits of a control system of an installation, said control system comprising at least one control unit, a power supply and at least two load circuits, each having at least one load unit, the at least two load circuits being supplied with at least one of a supply voltage and a supply current by the power supply via at least two output channels with at least one of variable voltage level and variable current level, and the at least two output channels and control outputs of the control unit being controlled by the control unit to produce installation states, the method comprising:
predefining installation states which are each subdivided at least into basic states and combination states, having assigned parameters to be determined being each installation state;
determining and storing reference values of the parameters for a respective predefined installation states;
determining and storing present parameter values for the respective predefined installation states;
comparing currently determined parameter values with corresponding reference values, determined parameter values with a respectively assigned installation state which deviate from the corresponding reference values being stored as elements in a divergence list;
filtering the divergence list, a check being performed to ascertain whether the installation state of the respective element is a basic state or a combination state for each element of the divergence list;
wherein the respective element is transferred to a results list if the installation state of the respective element is a basic state;
wherein a check is performed to determine whether the divergence list has at least one element with one of those basic states of which the combination state of the respective element is composed, if the installation state of the respective element is a combination state;
wherein the respective element is transferred to the results list if no such element is found in the divergence list; and
wherein, after finding at least one element with one of those basic states of which the combination state of the respective element is composed, the determined parameter value of the respective element is compared in the divergence list with the determined parameter of the at least one element found and the respective element is transferred to the results list if the determined parameter value of the respective element deviates in respect of value or type from the determined parameter value of the at least one element found.

12. The method as claimed in claim 11, wherein those elements of the results list having a basic state as an installation state are checked to ascertain whether determined parameter values which match with respect to value and type are listed for these elements.

13. The method as claimed in claim 11, wherein the results list is at least one of forwarded and output for further processing; and wherein elements of the results list with identical installation states are aggregated.

14. The method as claimed in claim 12, wherein the results list is at least one of forwarded and output for further processing; and wherein elements of the results list with identical installation states are aggregated.

15. The method as claimed in claim 11, wherein at least one of (i) at least one voltage at least one of the at least two output channels, (ii) a current at least one of the at least two output channels, (iii) a signal at least one control output of the control unit and (iii) a signal at least one input of the control unit are predefined as parameters to be determined depending on the respective installation state.

16. The method as claimed in claim 12, wherein at least one of (i) at least one voltage at least one of the at least two output channels, (ii) a current at least one of the at least two output channels, (iii) a signal at least one control output of the control unit and (iii) a signal at least one input of the control unit are predefined as parameters to be determined depending on the respective installation state.

17. The method as claimed in claim 13, wherein at least one of (i) at least one voltage at least one of the at least two output channels, (ii) a current at least one of the at least two output channels, (iii) a signal at least one control output of the control unit and (iii) a signal at least one input of the control unit are predefined as parameters to be determined depending on the respective installation state.

18. The method as claimed in claim 11, wherein the predefined installation states are processed in the same sequence when determining the reference values and when determining the current parameter values.

19. The method as claimed in claim 11, wherein a plurality of voltage values for the supply voltage are predefined for the predefined installation states.

20. The method as claimed in claim 19, wherein the predefined voltage values are increased in predefined voltage steps from an initial supply voltage up to a nominal voltage or up to an operating limit of the at least one load unit connected to the respective load circuit.

21. The method as claimed in claim 11, wherein a predefined wait time is observed when determining the reference values and when determining the present parameter values in an event of a change from one predefined installation state to another predefined installation state.

22. The method as claimed in claim 11, wherein the reference values of the predefined parameters for the predefined installation states are determined via a reference system.

23. The method as claimed in claim 11, wherein the reference values of the predefined parameters for the predefined installation states are determined during commissioning of the installation to be checked or during ongoing operation of the system to be checked.
